(19) United States
(12) Patent Application Publication
(10) Pub. No.: US 2008/0288853 A1
(43) Pub. Date: Nov. 20, 2008

(54) Apparatus and method of puncturing of error control codes

(75) Inventors: Jun Jin Kong, Yongin-si (KR); Jong Han Kim, Suwon-si (KR); Hong Rak Son, Suwon-si (KR); Young Hwan Lee, Suwon-si (KR); Sung Chung Park, Daejeon (KR); Seung-Hwan Song, Incheon (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/889,410

(22) Filed: Aug. 13, 2007

(30) Foreign Application Priority Data
May 14, 2007 (KR) 10-2007-0046566

(51) Int. Cl. H03M 13/03

(52) U.S. Cl. 714/790

(57) ABSTRACT

A code puncturing apparatus and method is provided. The apparatus includes: a codeword selection unit selecting continuous n−1-number of mother codewords from mother codewords generated from k-bit effective information, where k denotes a natural number, and one redundancy bit; and a puncturing unit selecting k-number of redundancy bits from redundancy bits included in the n−1-number of mother codewords, deleting remaining redundancy bits, and rearranging the n−1-number of mother codewords into an n·k bit-target codeword. Accordingly, a code rate of an Error Control Code (ECC) can be raised.

### CROSS-REFERENCE TO RELATED APPLICATION

This application claims the benefit of Korean Patent Application No. 10-2007-0046566, filed on May 14, 2007, in the Korean Intellectual Property Office, the disclosure of which is incorporated herein by reference.

### BACKGROUND OF THE INVENTION

1. Field of the Invention

The present invention relates to an Error Control Code (ECC), and more particularly, to a puncturing of an ECC for increasing the rate of the ECC.

2. Description of Related Art

An Error Control Code (ECC) is a technology with respect to a processing method of information which can add appropriate redundant information to effective information, and detect and correct an error generated during a process of transmitting information.

A route of transmitting the information may be generally referred to as a channel. When the process of transmitting the information is a wired communication, the channel is a communication line by which the information is transmitted. When the process of transmitting the information is a wireless communication, the channel is air through which an electromagnetic wave including the information passes.

Since an information error may be generated during a process of storing data including the information in a semiconductor memory device, and reading the stored data, a route of storing the data and reading the stored data is the channel in the semiconductor memory device.

In the semiconductor memory device, a point in time of storing the data and a point in time of outputting the stored data are generally different, and as a difference of both points in time becomes greater, a possibility that an error of the data is generated becomes greater.

Accordingly, a need for using the ECC in the semiconductor memory device is gradually increased. As a degree of integration of the semiconductor memory device is increased, this tendency is significantly shown.

Since the ECC adds the redundant information to the effective information, usage of the ECC requires a large storage area in the semiconductor memory device. As a ratio of the added redundant information to the effective information is increased, The performance of ECC is generally improved. However, since a burden of an additional storage area required for storing the data is also increased, it is required to find a trade-off between the the performance and the burden of the additional storage area.

Accordingly, a development of a code puncturing method which can improve the error control performance without a need for a large additional storage area is a very important matter.

### BRIEF SUMMARY

An aspect of the present invention provides a code puncturing apparatus and method which can reduce a code data storage area without reducing the performance of ECC.

An aspect of the present invention also provides a code puncturing apparatus and method which can generate an Error Control Code (ECC) appropriate for being applied to a semiconductor memory device.

An aspect of the present invention also provides a code puncturing apparatus and method which can increase the a code rate of an ECC.

An aspect of the present invention also provides a code puncturing apparatus and method which can reduce the complexity of a semiconductor memory control circuit.

According to an aspect of the present invention, there is provided a code puncturing apparatus, the apparatus including: a codeword selection unit selecting continuous n−1-number of mother codewords from mother codewords generated from k-bit effective information, where k denotes a natural number, and one redundancy bit; and a puncturing unit selecting k-number of redundancy bits from redundancy bits included in the n−1-number of mother codewords, deleting remaining redundancy bits, and rearranging the n−1-number of mother codewords into an n·k bit-target codeword.

According to another aspect of the present invention, there is provided a code puncturing method, the method including: selecting continuous n−1-number of mother codewords from mother codewords generated from k-bit effective information, where k denotes a natural number, and one redundancy bit; and selecting k-number of redundancy bits from redundancy bits included in the n−1-number of mother codewords, deleting remaining redundancy bits, and rearranging the n−1-number of mother codewords into an n·k bit-target codeword.

Additional aspects, features, and/or advantages of the invention will be set forth in part in the description which follows and, in part, will be apparent from the description, or may be learned by practice of the invention.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIG. 1 is a diagram illustrating a code puncturing process according to an exemplary embodiment of the present invention;

FIG. 2 is a block diagram illustrating a code puncturing apparatus according to an exemplary embodiment of the present invention;

FIG. 3 is a flowchart illustrating a code puncturing method according to an exemplary embodiment of the present invention; and

FIG. 4 is a flowchart illustrating operation S310 of FIG. 3 in detail.

### DETAILED DESCRIPTION OF EMBODIMENTS

Reference will now be made in detail to exemplary embodiments of the present invention, examples of which are illustrated in the accompanying drawings, wherein like reference numerals refer to the like elements throughout. Exemplary embodiments are described below to explain the present invention by referring to the figures.

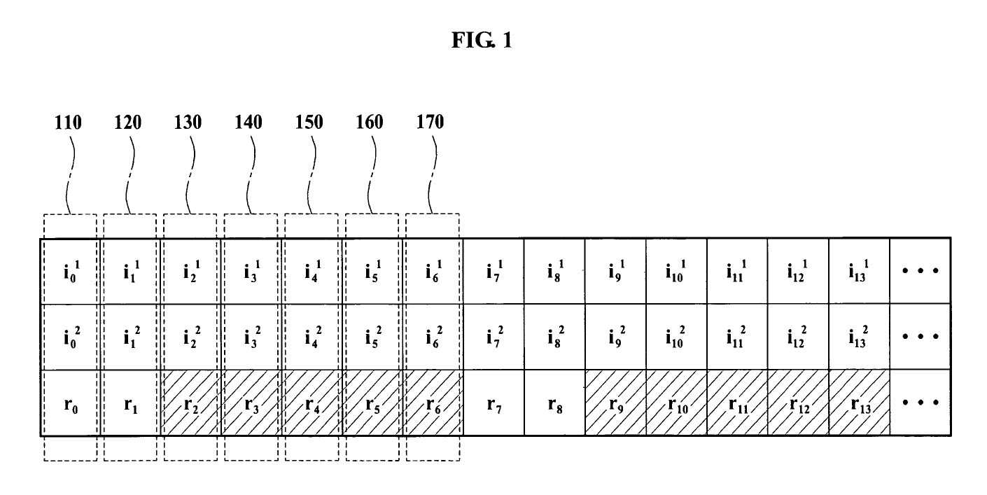

FIG. 1 is a diagram illustrating a code puncturing process according to an exemplary embodiment of the present invention.

Referring to FIG. 1, the code puncturing process according to the present exemplary embodiment of the present invention is applied to a mother code including mother codewords 110, 120, 130, 140, 150, 160, and 170 including 2-bit effective information and one redundancy bit.

The mother code has a code rate of ⅔. The code puncturing process converts the mother code having the code rate of ⅔ into a target code having a code rate of ⅞.

In this instance, when the code puncturing process is applied to a memory cell array, the code rate of ⅞ may be determined by a structure of the memory cell array. Accordingly, the code puncturing process according to the present invention may be appropriate for being applied to the memory cell array.

As an example of the mother codeword 110, i₀¹ and i₀² are bits respectively corresponding to effective information, and r₀ is a redundancy bit. As described above, a code in which the effective information and the redundancy bit are completely separated is referred to as a systematic code. Conversely, a code in which the effective information and the redundancy bit cannot be completely separated without a separate decoding process is referred to as a non-systematic code.

The non-systematic code may be converted into the systematic code by a recursive process. For example, when a generator g of the non-systematic code having a code rate of ½ is g=(g₀, g₁), a new generator g′ corresponding to the systematic code converted by the recursive process may be shown as g′=(1, g1/g0).

When the mother code is the systematic code, there is an advantage that an embodied circuit is simplified when the code puncturing process is embodied by a semiconductor circuit. In general cases where the code puncturing process is applied to a semiconductor memory circuit, the code puncturing process is embodied by a controller for controlling the semiconductor memory circuit or a peripheral circuit. There is an advantage that an area of the semiconductor memory circuit may be significantly reduced by simplifying the embodied circuit.

Accordingly, when a code initially generated based on the effective information is the non-systematic code, the code puncturing process may include a process of converting the initially-generated code into the systematic code by the recursive process.

A code rate is shown as a ratio of an effective information size of the code to a codeword size of the code. For example, an 8-bit code may include 7-bit effective information or a 16-bit code may include 14-bit effective information so that the code rate may be ⅞.

A process of converting the mother code having the code rate of ⅔ into the target code having the code rate of ⅞ is described as follows.

The seven mother codewords 110, 120, 130, 140, 150, 160, and 170 are selected and are grouped into one group.

The two mother codewords corresponding to a numerator 2 of the code rate of ⅔ of the mother code are selected in a group. In this instance, when the mother code is a convolutional code, the two mother codewords 110 and 120 from a head of the mother codewords are selected.

Generally, a convolutional code generated by a convolution operation for the effective information may be the non-systematic code. As described above, since the convolutional code being the non-systematic code may be converted into the systematic code by the recursive process, the code puncturing process selects and uses the convolutional code converted into the systematic code as the mother code.

As a head portion of the convolutional code includes an error, performance of the convolutional code is increasingly deteriorated. Since a puncturing process for the convolutional code performs a function similar to generating a type of error by deleting a portion of redundancy bits, a method of deleting the redundancy bits of the remaining mother codewords except for the redundancy bits included in the mother codewords of the head portion of the convolutional code has great performance.

Accordingly, redundancy bits r₂, r₃, r₄, r₅, and r₆, of the remaining mother codewords 130, 140, 150, 160, and 170, excluding redundancy bits r₀ and r₁ of the two mother codewords 110 and 120 from a head of the mother codewords, are deleted. Also, 16-bit data including the effective information of the seven mother codewords 110, 120, 130, 140, 150, 160, and 170 and redundancy bits r₀ and r₁ of the mother codewords 110 and 120 is rearranged, and a target codeword is generated.

Since the target codeword includes 14-bit effective information and two redundancy bits in 16-bit data, the target codeword has the code rate of ⅞.

A target code having a code rate of (n−1)/n may be generated from a mother code having a code rate of k/(k+1) by the code puncturing process according to another exemplary embodiment of the present invention.

The mother code includes mother codewords including k-bit effective information and one redundancy bit.

n−1-number of mother codewords are selected as one group, and redundancy bits of remaining mother codewords except for k-number of mother codewords from a head of the mother codewords in a group are deleted.

(n−1)·k-bit effective information and a k-bit redundancy bit are rearranged, and a target codeword is generated.

Since the target codeword includes the (n−1)·k-bit effective information from among [(n−1)·k+k]=n·k-bit data, the target codeword has the code rate (n−1)/n.

Accordingly, when a relation n>k is fulfilled, the target code has the code rate higher than the mother code.

Since a physical area in which the data being stored is limited in the semiconductor memory device, increasing amounts of data being stored in the limited physical area as a code rate of an Error Control Code (ECC) is increased. When the code rate of the ECC is high, error control performance may be generally reduced. However, when a data storage area additionally required is excessively increased in order to increase the performance of ECC up to a level higher than a general level, a cost of the semiconductor memory device is raised. Accordingly, it is required to find a trade-off between the performance of ECC and economic efficiency of the semiconductor memory device.

The code puncturing process of the present invention provides an appropriate ECC for being applied to the semiconductor memory device without significantly reducing the performance of ECC.

The code puncturing process generates the target code being the systematic code by selecting the systematic code as the mother code.

Since the effective information and the redundancy bit may be separated without another decoding process when the target code is the systematic code, the code puncturing process eliminates a need for an additional circuit and/or an operation unit when the effective information and the redundancy bit are separated during a process of storing the target code or reading the stored target code.

When the code puncturing process is applied to the semiconductor memory device, the code puncturing process is embodied by using the semiconductor circuit included in the peripheral circuit of the semiconductor memory device, the controller, and the like. In this instance, the code puncturing process has an effect of significantly reducing complexity of the semiconductor circuit included in the peripheral circuit, and the like.

Since a total area of the semiconductor memory device is reduced as complexity of the semiconductor circuit is reduced, the code puncturing process may contribute to significantly increasing the economic efficiency of the semiconductor memory device.

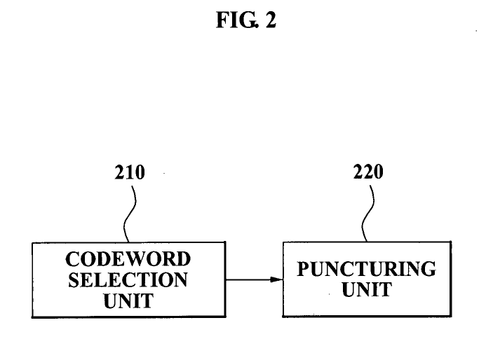

FIG. 2 is a block diagram illustrating a code puncturing apparatus according to an exemplary embodiment of the present invention.

Referring to FIG. 2, the code puncturing apparatus according to the present exemplary embodiment of the present invention includes a codeword selection unit 210 and a puncturing unit 220.

The codeword selection unit 210 selects continuous n−1-number of mother codewords from mother codewords generated from k-bit effective information, where k denotes a natural number, and one redundancy bit.

Each of the mother codes has a code rate of k/(k+1).

In this instance, each of the mother codewords may be a systematic code in which the effective information and the redundancy bit are separated.

In this instance, each of the mother codewords may be a convolutional code generated by a convolution operation for the effective information.

In this instance, when the convolutional code generated by the convolution operation for the effective information is a non-systematic code in which the effective information and the redundancy bit are not completely separated, the codeword selection unit 210 may convert the non-systematic code into the systematic code by a recursive process, and select the converted systematic code as the mother code.

In this instance, n may denote a predetermined natural number and may be determined by an array structure of a memory connected with the code puncturing apparatus.

When an array of the memory has a structure establishing 16 memory cells as one unit and repeating the unit, the natural number n may be determined as 16.

Since the array of the memory has a structure establishing 2^{M}-number of memory cells, where M denotes a natural number, as one unit and repeating the unit, the natural number n may be equal to 2^{M}.

The puncturing unit 220 selects k-number of redundancy bits from redundancy bits included in the n−1-number of mother codewords, deletes remaining redundancy bits, and rearranges the n−1-number of mother codewords into an n·k bit-target codeword.

A target code including the target codewords has a code rate (n−1)/n.

In this instance, the puncturing unit 220 may delete the remaining redundancy bits except for the k-number of redundancy bits included in the mother codeword from a head of the redundancy bits included in the n−1-number of mother codewords.

The codeword selection unit of the code puncturing apparatus according to another exemplary embodiment of the present invention may generate the systematic code including the one redundancy bit from the convolutional code generated by the convolution operation for the effective information by using a method of generating a recursive code, and select the systematic code as the mother code.

In this instance, the puncturing unit 220 may delete the remaining redundancy bits except for the k-number of redundancy bits included in the mother codeword from a head of the redundancy bits included in the n−1-number of mother codewords.

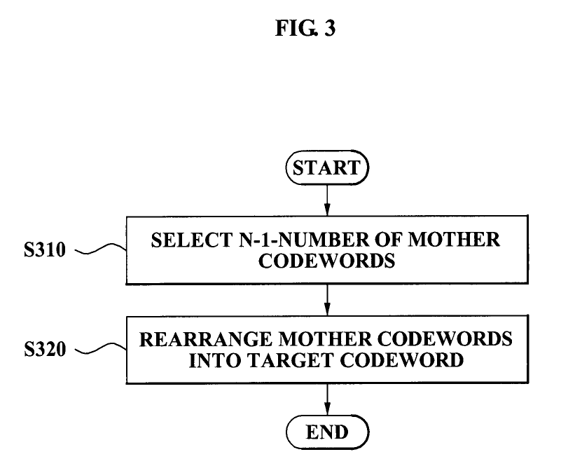

FIG. 3 is a flowchart illustrating a code puncturing method according to an exemplary embodiment of the present invention.

Referring to FIG. 3, the code puncturing method according to the present exemplary embodiment of the present invention selects continuous n−1-number of mother codewords from mother codewords generated from k-bit effective information, where k denotes a natural number, and one redundancy bit, in operation S310.

In this instance, each of the mother codewords may be a systematic code in which the effective information and the redundancy bit are separated.

In this instance, each of the mother codewords may be a convolutional code generated by a convolution operation for the effective information.

In this instance, when the convolutional code generated by the convolution operation for the effective information is a non-systematic code in which the effective information and the redundancy bit are not completely separated, the code puncturing method may convert the non-systematic code into the systematic code by a recursive process, and select the converted systematic code as the mother code.

In this instance, the predetermined natural number n may be determined by an array structure of a memory to which the code puncturing method is applied.

When an array of the memory has a structure establishing 16 memory cells as one unit and repeating the unit, n may denote a predetermined natural number and may be determined as 16.

Since the array of the memory has a structure establishing 2^{M}-number of memory cells, where M denotes a natural number, as one unit and repeating the unit, the natural number n may be equal to 2^{M}.

The code puncturing method selects k-number of redundancy bits from redundancy bits included in the n−1-number of mother codewords, deletes remaining redundancy bits, and rearranges the n−1-number of mother codewords into an n·k bit-target codeword, in operation S320.

A target code including the target codewords has a code rate (n−1)/n.

In this instance, the code puncturing method may delete the remaining redundancy bits except for the k-number of redundancy bits included in the mother codeword from a head of the redundancy bits included in the n−1-number of mother codewords.

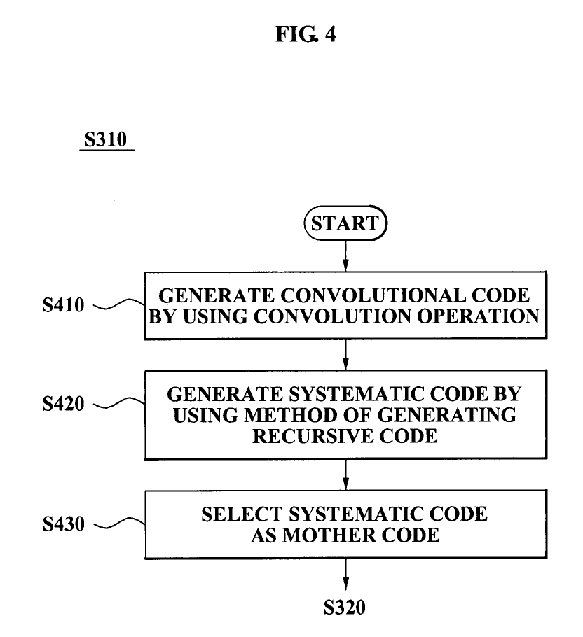

FIG. 4 is a flowchart illustrating operation S310 of a code puncturing method described with reference to FIG. 3, in detail.

Referring to FIG. 4, the code puncturing method according to the present exemplary embodiment of the present invention generates a convolutional code by using a convolution operation for effective information, in operation S410.

The code puncturing method generates a systematic code including one redundancy bit from the generated convolutional code by using a method of generating a recursive code, in operation S420.

The code puncturing method selects the generated systematic code as a mother code, in operation S430.

In this instance, the code puncturing method may delete the remaining redundancy bits except for the k-number of redundancy bits included in the mother codeword from a head of the redundancy bits included in the n−1-number of mother codewords.

The code puncturing method according to the above-described exemplary embodiments of the present invention may be recorded in computer-readable media including program instructions to implement various operations embodied by a computer. The media may also include, alone or in combination with the program instructions, data files, data structures, and the like. The media and program instructions may be those specially designed and constructed for the purposes of the present invention, or they may be of the kind well-known and available to those having skill in the computer software arts. Examples of computer-readable media include magnetic media such as hard disks, floppy disks, and magnetic tape; optical media such as CD ROM disks and DVD; magneto-optical media such as optical disks; and hardware devices that are specially configured to store and perform program instructions, such as read-only memory (ROM), random access memory (RAM), flash memory, and the like. The media may also be a transmission medium such as optical or metallic lines, wave guides, etc. including a carrier wave transmitting signals specifying the program instructions, data structures, etc. Examples of program instructions include both machine code, such as produced by a compiler, and files containing higher level code that may be executed by the computer using an interpreter. The described hardware devices may be configured to act as one or more software modules in order to perform the operations of the above-described exemplary embodiments of the present invention.

According to the above-described exemplary embodiments of the present invention, a code puncturing apparatus and method may reduce a code data storage area without reducing error control performance.

Also, according to the above-described exemplary embodiments of the present invention, a code puncturing apparatus and method may generate an ECC appropriate for being applied to a semiconductor memory device.

Also, according to the above-described exemplary embodiments of the present invention, a code puncturing apparatus and method may raise a code rate of an ECC.

Also, according to the above-described exemplary embodiments of the present invention, a code puncturing apparatus and method may reduce complexity of a semiconductor memory control circuit.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. A code puncturing apparatus, the apparatus comprising:
a codeword selection unit selecting continuous n−1-number of mother codewords from mother codewords generated from k-bit effective information, where k denotes a natural number, and one redundancy bit; and
a puncturing unit selecting k-number of redundancy bits from redundancy bits included in the n−1-number of mother codewords, deleting remaining redundancy bits, and rearranging the n−1-number of mother codewords into an n·k bit-target codeword.

2. The apparatus of claim 1, wherein n denotes a predetermined natural number, and is determined by an array structure of a memory connected with the apparatus.

3. The apparatus of claim i, wherein each of the mother codewords is a systematic code in which the effective information and the redundancy bit are separated.

4. The apparatus of claim 3, wherein each of the mother codewords is a convolutional code generated by a convolution operation for the effective information.

5. The apparatus of claim 4, wherein the puncturing unit deletes the remaining redundancy bits except for the k-number of redundancy bits from a head of the redundancy bits included in the n−1-number of mother codewords.

6. The apparatus of claim 1, wherein the codeword selection unit generates a systematic code including the one redundancy bit from a convolutional code generated by a convolution operation for the effective information by using a method of generating a recursive code, and selects the continuous n−1-number of mother codewords from the systematic code.

7. The apparatus of claim 6, wherein the puncturing unit deletes the remaining redundancy bits except for the k-number of redundancy bits from a head of the redundancy bits included in the n−1-number of mother codewords.

8. A code puncturing method, the method comprising:
selecting continuous n−1-number of mother codewords from mother codewords generated from k-bit effective information, where k denotes a natural number, and one redundancy bit; and
selecting k-number of redundancy bits from redundancy bits included in the n−1-number of mother codewords, deleting remaining redundancy bits, and rearranging the n−1-number of mother codewords into an n·k bit-target codeword.

9. The method of claim 8, wherein n denotes a predetermined natural number, and is determined by an array structure of a memory to which the method is applied.

10. The method of claim 8, wherein each of the mother codewords is a systematic code in which the effective information and the redundancy bit are separated.

11. The method of claim 10, wherein each of the mother codewords is a convolutional code generated by a convolution operation for the effective information.

12. The method of claim 11, wherein the selecting of the k-number of redundancy bits, deleting, and rearranging deletes the remaining redundancy bits except for the k-number of redundancy bits from a head of the redundancy bits included in the n−1-number of mother codewords.

13. The method of claim 8, wherein the selecting of the n−1-number of mother codewords generates a systematic code including the one redundancy bit from a convolutional code generated by a convolution operation for the effective information by using a method of generating a recursive code, and selects the continuous n−1-number of mother codewords from the systematic code.

14. The method of claim 13, wherein the selecting of the k-number of redundancy bits, deleting, and rearranging deletes the remaining redundancy bits except for the k-number of redundancy bits from a head of the redundancy bits included in the n−1-number of mother codewords.

15. A computer-readable recording medium storing a program for implementing a code puncturing method, the method comprising:
selecting continuous n−1-number of mother codewords from mother codewords generated from k-bit effective information, where k denotes a natural number, and one redundancy bit; and
selecting k-number of redundancy bits from redundancy bits included in the n−1-number of mother codewords, deleting remaining redundancy bits, and rearranging the n−1-number of mother codewords into an n·k bit-target codeword.
